(19) United States
(12) Patent Application Publication
(10) Pub. No.: US 2024/0258281 A1
(43) Pub. Date: Aug. 1, 2024

(54) DISPLAY DEVICE

(71) Applicant: LG Display Co., Ltd., Seoul (KR)

(72) Inventors: JongBeom LEE, Paju-si (KR); SunHwa LEE, Goyang-si (KR); ByungHyun LEE, Paju-si (KR); Soyi LEE, Paju-si (KR); Seeun KIM, Seoul (KR)

(73) Assignee: LG Display Co., Ltd., Seoul (KR)

(21) Appl. No.: 18/416,530

(22) Filed: Jan. 18, 2024

(30) Foreign Application Priority Data
Jan. 30, 2023 (KR) 10-2023-0011840

(51) Int. Cl. H01L 25/075; H01L 25/16; H01L 33/00; H01L 33/10; H01L 33/38

(52) U.S. Cl. CPC H01L 25/0753; H01L 25/167; H01L 33/0093; H01L 33/10; H01L 33/387

(57) ABSTRACT

A display device in one aspect includes a plurality of sub-pixels having an emission sub-pixel and a repair sub-pixel. The display device further includes a light emitting element disposed in the emission sub-pixel and a transistor disposed in the emission sub-pixel. The display device further includes a first reflective layer disposed between the light emitting element and the transistor in the emission sub-pixel, and electrically connected to the transistor. The display device also includes a second reflective layer disposed in the repair sub-pixel, and a connection layer disposed below the first reflective layer and the second reflective layer to overlap the first reflective layer and the second reflective layer. Therefore, defective sub-pixels can be easily repaired.

### CROSS-REFERENCE TO RELATED APPLICATIONS

This application claims priority to Korean Patent Application No. 10-2023-0011840 filed on Jan. 30, 2023, in the Republic of Korea, the entire contents of which are hereby expressly incorporated by reference into the present application.

### BACKGROUND

### Technical Field

The present disclosure relates to a display device, and more particularly, to a display device allowing for repairs of defective sub-pixels.

### Discussion of the Related Art

Display devices used in computer monitors, TVs, and mobile phones include organic light emitting displays (OLEDs) that emit light by themselves, and liquid crystal displays (LCDs) that require a separate light source.

Display devices are being applied to various fields of application including not only computer monitors and TVs, but also personal mobile devices. Thus, display devices having a reduced volume and weight while having a wide active area are being studied.

In recent years, display devices including light emitting diodes LED have received attention as the next-generation display devices. Since the LED is formed of an inorganic material rather than an organic material, it has excellent reliability and has a longer lifespan compared to a liquid crystal display or an organic light emitting display. In addition, the LED has a high lighting speed, high luminous efficiency and excellent stability due to high impact resistance and can display a high-luminance image.

### SUMMARY OF THE DISCLOSURE

An object to be achieved by the present disclosure is to provide a display device capable of easily performing repairs on a high-resolution display device.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device comprises a plurality of sub-pixels including an emission sub-pixel and a repair sub-pixel. The display device comprises a light emitting element disposed in the emission sub-pixel. The display device comprises a transistor disposed in the emission sub-pixel. The display device comprises a first reflective layer disposed between the light emitting element and the transistor in the emission sub-pixel, and electrically connected to the transistor. The display device comprises a second reflective layer disposed in the repair sub-pixel. The display device comprises a connection layer disposed below the first reflective layer and the second reflective layer to overlap the first reflective layer and the second reflective layer. Therefore, defective sub-pixels can be easily repaired.

Other detailed matters of the exemplary embodiments are included in the detailed description and the drawings.

In the present disclosure, a high-resolution display device can be implemented by reducing a repair area.

In the present disclosure, a manufacturing cost of a display device can be minimized by transferring a repair light emitting element only when a defect occurs.

Other detailed matters of the exemplary embodiments are included in the detailed description and the drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a schematic configuration diagram of a display device according to an exemplary embodiment of the present disclosure.

FIG. 2 is an enlarged plan view of a display device according to an exemplary embodiment of the present disclosure.

FIG. 3 is a cross-sectional view taken along line A-A′ of FIG. 2.

FIGS. 4A to 4C are cross-sectional views for explaining a process of manufacturing the display device according to an exemplary embodiment of the present disclosure.

FIG. 5 is an enlarged plan view of a display device according to another exemplary embodiment of the present disclosure.

FIG. 6 is a cross-sectional view taken along line B-B′ of FIG. 5.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “comprising,” “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, “under”, “next”, etc., one or more parts can be positioned between the two parts unless the terms are used with the term “immediately” or “directly”.

When an element or layer is disposed “on” another element or layer, one or more other layers or elements can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “exemplary” or “exemplarily” is used to mean an example, and is interchangeably used with the term “example”. Further, embodiments are example embodiments and aspects are example aspects. Any implementation described herein as an “exemplary”, “exemplarily” or “example” is not necessarily to be construed as preferred or advantageous over other implementations.

Hereinafter, a display device according to exemplary embodiments of the present disclosure will be described in detail with reference to accompanying drawings. All the components of each display device or apparatus according to all embodiments of the present disclosure are operatively coupled and configured.

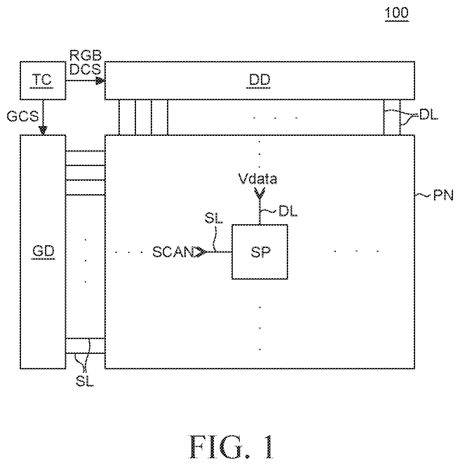

FIG. 1 is a schematic configuration diagram of a display device according to an exemplary embodiment of the present disclosure.

In FIG. 1, a display panel PN, a gate driver GD, a data driver DD, and a timing controller TC among various components of a display device 100 are illustrated for convenience of description.

Referring to FIG. 1, a display device 100 includes the display panel PN including a plurality of sub-pixels SP, the gate driver GD and the data driver DD for supplying various signals to the display panel PN, and the timing controller TC for controlling the gate driver GD and the data driver DD.

The display panel PN, a component for displaying an image to a user, includes the plurality of sub-pixels SP. In the display panel PN, a plurality of scan lines and a plurality of data lines cross each other, and each of the plurality of sub-pixels SP is connected to a scan line SL and a data line DL. In addition, each of the plurality of sub-pixels SP can be connected to high potential power supply lines, low potential power supply lines, and the like.

The plurality of sub-pixels SP are minimum units constituting a screen, and each of the plurality of sub-pixels SP includes a light emitting element and a pixel circuit for driving the corresponding light emitting element. A plurality of light emitting elements can be differently defined according to a type of display panel PN. For example, when the display panel PN is an inorganic light emitting display panel, the light emitting element can be a light emitting diode (LED) or a micro-light emitting diode (micro-LED).

The gate driver GD supplies a plurality of scan signals SCAN to the plurality of scan lines SL according to a plurality of gate control signals GCS provided from the timing controller TC. Although it is illustrated in FIG. 1 that one gate driver GD is disposed to be spaced apart from one side of the display panel PN, the number and arrangement of gate drivers GD are not limited thereto. For example, the gate driver GD can be disposed within the display area.

The data driver DD converts image data RGB input from the timing controller TC into a data voltage Vdata using a reference gamma voltage according to a plurality of data control signals DCS provided from the timing controller TC. The data driver DD can supply the converted data voltage Vdata to the plurality of data lines DL.

The timing controller TC aligns image data RGB input from the outside and supplies it to the data driver DD. The timing controller TC can generate the gate control signal GCS and the data control signal DCS using synchronization signals input from the outside, for example, a dot clock signal, a data enable signal, and a horizontal/vertical synchronization signal. In addition, the timing controller TC can supply the generated gate control signal GCS and data control signal DCS to the gate driver GD and the data driver DD, respectively, to thereby control the gate driver GD and the data driver DD.

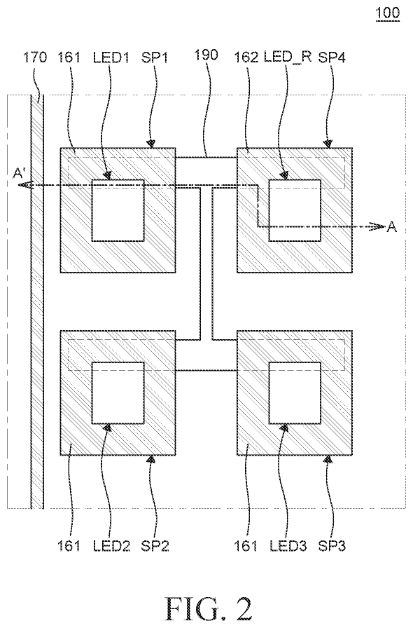

Hereinafter, a more detailed description of the display panel PN of the display device 100 will be provided with reference to FIGS. 2 to 4.

FIG. 2 is an enlarged plan view of the display device according to an exemplary embodiment of the present disclosure. In FIG. 2, for brevity of the drawings, the plurality of sub-pixels SP, a plurality of light emitting elements LED, a plurality of first reflective layers 161, a second reflective layer 162, a connection layer 190, and an intermediate line 170 are illustrated, and hatching is not provided to the light emitting element LED.

Referring to FIG. 2, the plurality of sub-pixels SP are disposed in the display device 100. The plurality of sub-pixels SP can include a first sub-pixel SP1, a second sub-pixel SP2, a third sub-pixel SP3, and a fourth sub-pixel SP4.

Among the plurality of sub-pixels SP, each of the first sub-pixel SP1, the second sub-pixel SP2, and the third sub-pixel SP3 can include a plurality of transistors and a storage capacitor. Meanwhile, a transistor and a storage capacitor may not be disposed in the fourth sub-pixel SP4 among the plurality of sub-pixels SP.

The plurality of first reflective layers 161 can be disposed in the first sub-pixel SP1, the second sub-pixel SP2, and the third sub-pixel SP3 among the plurality of sub-pixels SP. The plurality of first reflective layers 161 are disposed to be spaced apart from each other in the first sub-pixel SP1, the second sub-pixel SP2, and the third sub-pixel SP3, respectively, and can be electrically connected to the plurality of transistors disposed in the first sub-pixel SP1, the second sub-pixel SP2, and the third sub-pixel SP3, respectively.

The second reflective layer 162 can be disposed in the fourth sub-pixel SP4 among the plurality of sub-pixels SP.

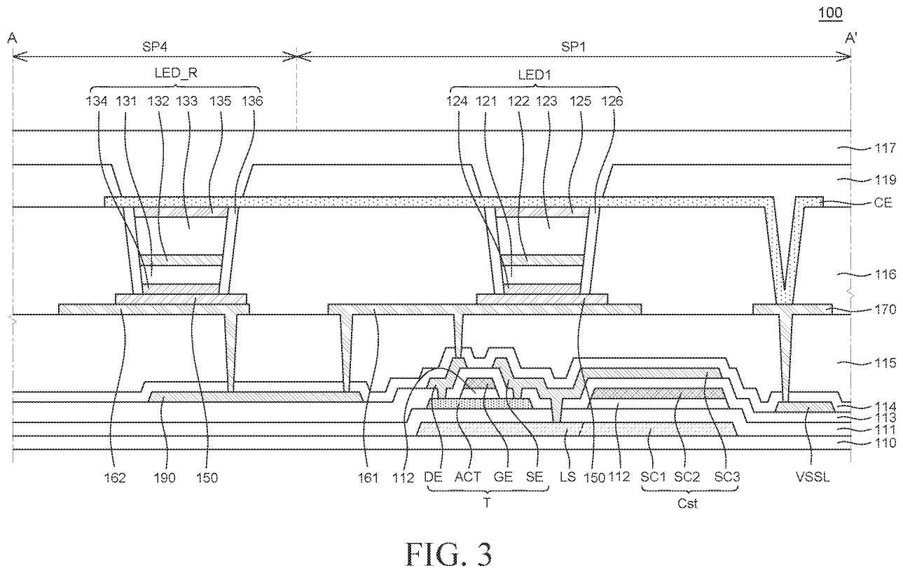

The detailed description of the second reflective layer 162 will be described later with reference to FIG. 3.

The connection layer 190 can be disposed below the plurality of first reflective layers 161 and the second reflective layer 162.

The connection layer 190 is disposed to extend between the plurality of first reflective layers 161 and the second reflective layer 162 and can overlap the plurality of first reflective layers 161 and the second reflective layer 162.

The detailed description of the connection layer 190 will be described later with reference to FIG. 3.

Referring to FIG. 2, the intermediate line 170 is disposed. The intermediate line 170 is connected to a low potential power supply line VSSL disposed on a substrate 110 and can transmit a low potential power supply voltage to the plurality of light emitting elements LED.

The light emitting element LED can be disposed in each of the plurality of sub-pixels SP. For example, a first light emitting element LED1, a second light emitting element LED2, a third light emitting element LED3, and a repair light emitting element LED_R can be disposed in the first sub-pixel SP1, the second sub-pixel SP2, the third sub-pixel SP3, and the fourth sub-pixel SP4, respectively.

At this time, light emitting elements that emit different colors of light can be disposed in the first sub-pixel SP1, the second sub-pixel SP2, and the third sub-pixel SP3 among the plurality of sub-pixels SP, respectively. For example, the first light emitting element LED1 disposed in the first sub-pixel SP1 can be a red light emitting element that emits red light, the second light emitting element LED2 disposed in the second sub-pixel SP2 can be a green light emitting element that emits green light, and the third light emitting element LED3 disposed in the third sub-pixel SP3 can be a blue light emitting element that emits blue light. However, the first to third light emitting elements LED1 to LED3 can emit different color lights.

Meanwhile, one of the first sub-pixel SP1, the second sub-pixel SP2, and the third sub-pixel SP3 can be considered a defective sub-pixel (e.g., can be detected to be defective), and the fourth sub-pixel SP4 can be provided as a repair sub-pixel.

In this case, in the fourth sub-pixel SP4, the repair light emitting element LED_R that emits light of the same color as the light emitting element disposed in the defective sub-pixel can be disposed. For example, when the first light emitting element LED1 is a red light emitting element, the second light emitting element LED2 is a green light emitting element, the third light emitting element LED3 is a blue light emitting element, and the first sub-pixel SP1 in which the first light emitting element LED1 is disposed is (or detected to be) defective, the repair light emitting element LED_R disposed in the fourth sub-pixel SP4 can be provided as a light emitting element that emits red light.

Hereinafter, with reference to FIG. 3, a plurality of transistors and a storage capacitor of the display device 100 according to an exemplary embodiment of the present disclosure will be described in detail.

FIG. 3 is a cross-sectional view taken along line A-A′ of FIG. 2. In FIG. 3, for convenience of explanation, a description is made assuming that the first sub-pixel SP1 among the plurality of sub-pixels SP is detected to be a defective sub-pixel, but the description is also applied or equally applicable in the same manner when the second sub-pixel SP2 or the third sub-pixel SP3 is detected to be defective.

Referring to FIG. 3, the display panel PN includes the substrate 110, a light blocking layer LS, a buffer layer 111, a gate insulating layer 112, an interlayer insulating layer 113, a first passivation layer 114, a first planarization layer 115, the plurality of first reflective layers 161, the second reflective layer 162, a plurality of bonding layers 150, a second planarization layer 116, a third planarization layer 117, the connection layer 190, the intermediate line 170, the low potential power supply line VSSL, a common electrode CE, transistors T, a storage capacitor Cst, and the light emitting elements LED.

The substrate 110 is a component to support various components included in the display panel PN and can be formed of an insulating material. For example, the substrate 110 can be formed of glass or resin or the like. In addition, the substrate 110 can be formed to include polymer or plastic or can be formed of a material with flexibility.

The light blocking layer LS and a first capacitor electrode SC1 are disposed on the substrate 110.

The light blocking layer LS is disposed on the substrate 110 in the sub-pixel SP. The light blocking layer LS can be disposed in the first sub-pixel SP1, the second sub-pixel SP2, and the third sub-pixel SP3 among the plurality of sub-pixels SP.

The light blocking layer LS can be disposed in areas overlapping with a plurality of the transistors T to block light incident on the plurality of transistors T from a bottom of the substrate 110 and minimize leakage current. For example, the light blocking layer LS can block light incident on active layers ACT of the plurality of transistors T.

The storage capacitor Cst is disposed on the substrate 110 in the sub-pixel SP. The storage capacitor Cst can be disposed in the first sub-pixel SP1, the second sub-pixel SP2, and the third sub-pixel SP3 among the plurality of sub-pixels SP.

The storage capacitor Cst can include the first capacitor electrode SC1, a second capacitor electrode SC2, and a third capacitor electrode SC3.

The first capacitor electrode SC1 is disposed on the substrate 110. The first capacitor electrode SC1 can form the storage capacitor Cst together with other capacitor electrodes. The first capacitor electrode SC1 can be formed integrally with the light blocking layer LS, but is not limited thereto.

Meanwhile, various signal lines, such as high potential power supply lines and data lines, can be disposed on the substrate 110.

The buffer layer 111 is disposed on the light blocking layer LS and the first capacitor electrode SC1. The buffer layer 111 can reduce penetration of moisture or impurities through the substrate 110. The buffer layer 111 can be composed of, for example, a single layer or multiple layers of silicon oxide (SiOx) or silicon nitride (SiNx), but is not limited thereto. However, the buffer layer 111 can be omitted depending on a type of the substrate 110 or a type of the transistor, but is not limited thereto.

The plurality of transistors T are disposed on the buffer layer 111. The plurality of transistors T can be used as driving elements of the display device. The plurality of transistors T can be, for example, a thin film transistor (TFT), an N-channel metal oxide semiconductor (NMOS), a P-channel metal oxide semiconductor (PMOS), a complementary metal oxide semiconductor (CMOS), a field effect transistor (FET), and the like, but is not limited thereto. Hereinafter, a description will be made assuming that the plurality of transistors T are thin film transistors, but the present disclosure is not limited thereto.

The plurality of transistors T can be disposed in the first sub-pixel SP1, the second sub-pixel SP2, and the third sub-pixel SP3 among the plurality of sub-pixels SP.

Each of the plurality of transistors T includes a gate electrode GE, the active layer ACT, a source electrode SE, and a drain electrode DE.

The active layer ACT is disposed on the buffer layer 111. The active layer ACT can be formed of a semiconductor material such as an oxide semiconductor, amorphous silicon, or polysilicon, but is not limited thereto.

The gate insulating layer 112 is disposed on the active layer ACT. The gate insulating layer 112 is an insulating layer to insulate the active layer ACT and the gate electrode GE, and can be composed of a single layer or multiple layers of silicon oxide (SiOx) or silicon nitride (SiNx), but is not limited thereto.

The gate electrode GE is disposed on the gate insulating layer 112. The gate electrode GE can be formed of a conductive material, such as copper (Cu), aluminum (Al), molybdenum (Mo), nickel (Ni), titanium (Ti), chromium (Cr), or an alloy thereof, but is not limited thereto.

The interlayer insulating layer 113 is disposed on the gate electrode GE. Contact holes for respectively connecting the source electrode SE and the drain electrode DE to the active layer ACT are formed in the interlayer insulating layer 113. The interlayer insulating layer 113 is an insulating layer to protect components below the interlayer insulating layer 113, and can be composed of a single layer or multiple layers of silicon oxide (SiOx) or silicon nitride (SiNx), but is not limited thereto.

The source electrode SE and the drain electrode DE that are electrically connected to the active layer ACT are disposed on the interlayer insulating layer 113. The drain electrode DE can be connected to the active layer ACT, and the source electrode SE can be connected to the active layer ACT. The source electrode SE and the drain electrode DE can be formed of a conductive material, such as copper (Cu), aluminum (Al), molybdenum (Mo), nickel (Ni), titanium (Ti), chromium (Cr), or an alloy thereof, but is not limited thereto.

Referring to FIGS. 2 and 3, the low potential power supply line VSSL can be disposed on the interlayer insulating layer 113. The low potential power supply line VSSL can be disposed to extend in a column direction (e.g., any set direction). The low potential power supply line VSSL can be electrically connected to the plurality of light emitting elements LED disposed in the same row through the common electrode CE, but is not limited thereto.

Referring to FIGS. 2 and 3, the connection layer 190 can be disposed on the interlayer insulating layer 113. The connection layer 190 can be formed of the same material as the conductive material disposed on the substrate 110. For example, the connection layer 190 can be formed of the same material as the source electrode SE or drain electrode DE of the plurality of transistors T. For example, the connection layer 190 can be formed of copper (Cu), aluminum (Al), molybdenum (Mo), titanium (Ti), or an alloy thereof, but is not limited thereto.

The connection layer 190 can be disposed to overlap the plurality of first reflective layers 161 and the second reflective layer 162 that are disposed on the connection layer 190. For example, the connection layer 190 can be disposed below the plurality of first reflective layers 161 and the second reflective layer 162.

The connection layer 190 can be electrically connected to the second reflective layer 162. In addition, the connection layer 190 can be electrically connected to the first reflective layer 161 disposed in the defective sub-pixel. For example, as illustrated in FIG. 3, the connection layer 190 can be electrically connected to the first reflective layer 161 disposed in the first sub-pixel SP1. Meanwhile, the connection layer 190 can be insulated from the first reflective layers 161 disposed in the second sub-pixel SP2 and the third sub-pixel SP3.

Next, the second capacitor electrode SC2 is disposed on the gate insulating layer 112. The second capacitor electrode SC2 is one of the electrodes forming the storage capacitor Cst, and can be disposed to overlap the first capacitor electrode SC1. The second capacitor electrode SC2 is formed integrally with the gate electrode GE of the transistor T, and can be electrically connected to the gate electrode GE. The first capacitor electrode SC1 and the second capacitor electrode SC2 can be disposed to be spaced apart from each other with the buffer layer 111 and the gate insulating layer 112 interposed therebetween.

The third capacitor electrode SC3 is disposed on the interlayer insulating layer 113. The third capacitor electrode SC3 is an electrode that constitutes the storage capacitor Cst, and can be disposed to overlap the first capacitor electrode SC1 and the second capacitor electrode SC2. The third capacitor electrode SC3 can be formed integrally with the source electrode SE of the transistor T and can be electrically connected to the source electrode SE. In addition, the source electrode SE can be electrically connected to the first capacitor electrode SC1 through contact holes formed in the interlayer insulating layer 113 and the buffer layer 111. Accordingly, the first capacitor electrode SC1 and the third capacitor electrode SC3 can be electrically connected to the source electrode SE of the transistor T.

The storage capacitor Cst stores a potential difference between the gate electrode GE and the source electrode SE of the transistor T while the light emitting element LED emits light, so that a constant current can be supplied to the light emitting element LED. The storage capacitor Cst can include the first capacitor electrode SC1 that is formed on the substrate 110 and connected to the source electrode SE, the second capacitor electrode SC2 that is formed on the buffer layer 111 and the gate insulating layer 112 and connected to the gate electrode GE, and the third capacitor electrode SC3 that is formed on the second capacitor electrode SC2 and the interlayer insulating layer 113 and connected to the source electrode SE, and store a voltage between the gate electrode GE and the source electrode SE of the transistor T.

The first passivation layer 114 is disposed on the plurality of transistors T and the storage capacitor Cst. The first passivation layer 114 is an insulating layer to protect components below the first passivation layer 114, and can be composed of a single layer or multiple layers of silicon oxide (SiOx) or silicon nitride (SiNx), but is not limited thereto.

The first planarization layer 115 is disposed on the first passivation layer 114. The first planarization layer 115 can planarize an upper portion of the substrate 110 on which the plurality of transistors T and the storage capacitor Cst are disposed. The first planarization layer 115 can be composed of a single layer or multiple layers, and can be formed of, for example, photoresist or an acryl-based organic material, but the present disclosure is not limited thereto.

A passivation layer can be separately disposed on the first planarization layer 115, but is not limited thereto.

Referring to FIGS. 2 and 3, the plurality of first reflective layers 161 and the second reflective layer 162 are disposed on the first planarization layer 115.

The plurality of first reflective layers 161 and the second reflective layer 162 are disposed below the plurality of light emitting elements LED and can reflect light that is emitted to lower surfaces of the plurality of light emitting elements LED among light emitted from the plurality of light emitting elements LED, upwardly of the substrate 110, thereby improving luminous efficiency of the plurality of light emitting elements LED.

The plurality of first reflective layers 161 and the second reflective layer 162 can be formed of conductive layers with excellent reflectivity, for example, silver (Ag), nickel (Ni), gold (Au), platinum (Pt), aluminum (Al), copper (Cu), or molybdenum/aluminum neodymium (Mo/AlNd), but the present disclosure is not limited thereto.

Referring to FIG. 3, the plurality of first reflective layers 161 can be disposed between the plurality of light emitting elements LED and the plurality of transistors T in each of the first sub-pixel SP1, the second sub-pixel SP2, and the third sub-pixel SP3, and can be electrically connected to the plurality of transistors T.

The second reflective layer 162 disposed in the fourth sub-pixel SP4 can be electrically connected to the connection layer 190 through a contact hole formed in the first planarization layer 115.

The first reflective layer 161 can be disposed on the same layer as the second reflective layer 162 in the fourth sub-pixel SP4. Referring to FIG. 3, the first reflective layer 161 can be electrically connected to the connection layer 190. For example, the first reflective layer 161 can be electrically connected to the connection layer 190 through a laser welding process, but is not limited thereto. For example, the connection layer 190 and the first reflective layer 161 are in an initially insulated state. However, in a situation, when the first light emitting element LED1 of the first sub-pixel SP1 is determined (or detected) to be defective, the connection layer 190 and the first reflective layer 161 can be electrically connected through a laser welding process. Although FIG. 3 illustrates that the connection layer 190 and the first reflective layer 161 are naturally connected, a shape of the connection layer 190 and the first reflective layer 161 connected through a laser welding process can be formed randomly.

Meanwhile, in FIG. 3, only the first reflective layer 161 disposed in the first sub-pixel SP1 is illustrated, but the connection layer 190 and the first reflective layers 161 disposed in the sub-pixels SP other than the fourth sub-pixel SP4 and the defective sub-pixel can be in an insulated state. The first reflective layers 161 disposed in the second sub-pixel SP2 and the third sub-pixel SP3 can be insulated from the connection layer 190.

Referring to FIGS. 2 and 3, the intermediate line 170 can be disposed on the first planarization layer 115. The intermediate line 170 is disposed to extend in the column direction and can be connected to the low potential power supply line VSSL. The intermediate line 170 is disposed to overlap the low potential power supply line VSSL and can be electrically connected to the plurality of light emitting elements LED disposed in the same row through the common electrode CE, but the present disclosure is not limited thereto.

The intermediate line 170 can be formed of the same material as the plurality of first reflective layers 161 and the second reflective layer 162 on the same layer as the plurality of first reflective layers 161 and the second reflective layer 162. For example, the intermediate line 170 can be formed of silver (Ag), nickel (Ni), gold (Au), platinum (Pt), aluminum (Al), copper (Cu), and molybdenum/aluminum neodymium (Mo/AlNd), but is not limited thereto.

The plurality of bonding layers 150 are disposed on the plurality of first reflective layers 161 and the second reflective layer 162. The plurality of bonding layers 150 are disposed to be spaced apart from each other in the plurality of sub-pixels SP and allow the plurality of light emitting elements LED to be bonded onto a layer formed on the display panel PN, simultaneously with transfer of the plurality of light emitting elements LED. For example, the plurality of bonding layers 150 electrically connect each of the plurality of first reflective layers 161 and the second reflective layer 162 and each of the plurality of light emitting elements LED by a bonding method using heat compression at a high temperature. Accordingly, the plurality of transistors T and the plurality of light emitting elements LED can be electrically connected through the plurality of bonding layers 150, respectively. In this case, the plurality of bonding layers 150 can be formed of eutectic metal, for example, tin (Sn), indium (In), zinc (Zn), lead (Pb), nickel (Ni), gold (Au), platinum (Pt), copper (Cu) or the like, but the present disclosure is not limited thereto, and other bonding methods can be used.

The plurality of light emitting elements LED are disposed on the plurality of bonding layers 150. The plurality of light emitting elements LED are disposed in the plurality of sub-pixels SP.

Meanwhile, the plurality of light emitting elements LED can be formed in various structures such as a horizontal structure, a vertical structure, and a flip structure. An LED with the horizontal structure includes a light emitting layer and an N-type electrode and a P-type electrode disposed horizontally on both sides of the light emitting layer. An LED with the horizontal structure can emit light by combining electrons supplied to the light emitting layer through the N-type electrode and holes supplied to the light emitting layer through the P-type electrode. An LED of the vertical structure includes a light emitting layer, and an N-type electrode and a P-type electrode disposed above and below the light emitting layer. Like LEDs with the horizontal structure, LEDs of the vertical structure can also emit light by combining electrons and holes supplied from electrodes. An LED of the flip structure has substantially the same structure as the LED with the horizontal structure. However, LEDs with the flip structure can be directly attached to a printed circuit board or the like with omission of a medium such as a metal wire. Hereinafter, for convenience of explanation, a description will be made on the assumption that the plurality of light emitting elements LED have a vertical structure, but the present disclosure is not limited thereto.

Meanwhile, the first light emitting element LED1 disposed in the first sub-pixel SP1 among the plurality of light emitting elements LED can be determined to be a defective light emitting element that does not emit light. Then, the repair light emitting element LED_R disposed in the fourth sub-pixel SP4 among the plurality of sub-pixels SP can emit light of the same color as the first light emitting element LED1, which is the defective light emitting element, to compensate for the defective first light emitting element LED1.

The first light emitting element LED1 is disposed on the bonding layer 150 overlapping with the first reflective layer 161 in the first sub-pixel SP1.

The first light emitting element LED1 includes a first p-type semiconductor layer 121, a first light emitting layer 122, a first n-type semiconductor layer 123, a first p-type electrode 124, a first n-type electrode 125, and a first encapsulation layer 126.

The first p-type semiconductor layer 121 of the first light emitting element LED1 is disposed on the bonding layer 150 of the first sub-pixel SP1, and the first n-type semiconductor layer 123 is disposed on the first p-type semiconductor layer 121. The first p-type semiconductor layer 121 and the first n-type semiconductor layer 123 can be layers formed by implanting n-type impurities or p-type impurities into gallium nitride (GaN). For example, the first p-type semiconductor layer 121 can be a layer formed by implanting a p-type impurity into gallium nitride, and the first n-type semiconductor layer 123 can be a layer formed by implanting an n-type impurity into gallium nitride, but the present disclosure is not limited thereto. The p-type impurity can be magnesium (Mg), zinc (Zn), beryllium (Be) or the like, and the n-type impurity can be silicon (Si), germanium (Ge), tin (Sn) or the like, but the present disclosure is not limited thereto.

The first light emitting layer 122 is disposed between the first p-type semiconductor layer 121 and the first n-type semiconductor layer 123. The first light emitting layer 122 can emit light by receiving holes and electrons from the first p-type semiconductor layer 121 and the first n-type semiconductor layer 123. The first light emitting layer 122 can have a single or multi-quantum well (MQW) structure. For example, the first light emitting layer 122 can be formed of indium gallium nitride (InGaN), gallium nitride (GaN) or the like, but is not limited thereto.

The first p-type electrode 124 is disposed between the first p-type semiconductor layer 121 and the bonding layer 150. The first p-type electrode 124 can be electrically connected to the first p-type semiconductor layer 121. The first p-type electrode 124 can be in contact with a lower surface of the first p-type semiconductor layer 121, and the bonding layer 150 can be in contact with a lower surface of the first p-type electrode 124. Accordingly, in the first sub-pixel SP1, the transistor T can be electrically connected to the first light emitting element LED1 through the bonding layer 150 and the first p-type electrodes 124. Specifically, a voltage from the transistor T can be applied to the first p-type semiconductor layer 121 of the first light emitting element LED1 through the bonding layer 150 and the first p-type electrode 124. Electrons or holes can be supplied to the first light emitting layer 122 of each first light emitting element LED1.

The first n-type electrode 125 is disposed on the first n-type semiconductor layer 123. The first n-type electrode 125 can be electrically connected to the first n-type semiconductor layer 123. The first n-type electrode 125 can be in contact with an upper surface of the first n-type semiconductor layer 123 and electrically connected to the first n-type semiconductor layer 123.

Referring to FIG. 3, the first encapsulation layer 126 can be disposed to surround at least portions of the first p-type semiconductor layer 121, the first light emitting layer 122, the first n-type semiconductor layer 123, the first p-type electrode 124, and the first n-type electrode 125. The first encapsulation layer 126 is formed of an insulating material and can protect the first p-type semiconductor layer 121, the first light emitting layer 122, and the first n-type semiconductor layer 123. The first encapsulation layer 126 can be disposed to cover a portion of a side surface of the first p-type semiconductor layer 121 adjacent to the first light emitting layer 122 and a portion of a side surface of the first n-type semiconductor layer 123 adjacent to the first light emitting layer 122. The first p-type electrode 124 and the first n-type electrode 125 can be exposed from the first encapsulation layer 126, and the first p-type electrode 124 and the bonding layer 150 can be electrically connected. And the first n-type electrode 125 and the common electrode CE to be formed later can be electrically connected.

The repair light emitting element LED_R is disposed on the bonding layer 150 overlapping with the second reflective layer 162 in the fourth sub-pixel SP4.

The repair light emitting element LED_R can include a fourth p-type semiconductor layer 131, a fourth light emitting layer 132, a fourth n-type semiconductor layer 133, a fourth p-type electrode 134, a fourth n-type electrode 135, and a fourth encapsulation layer 135.

Since the fourth p-type semiconductor layer 131, the fourth light emitting layer 132, the fourth n-type semiconductor layer 133, the fourth p-type electrode 134, the fourth n-type electrode 135, and the fourth encapsulation layer 136 of the repair light emitting element LED_R are substantially identical to the first p-type semiconductor layer 121, the first light emitting layer 122, the first n-type semiconductor layer 123, the first p-type electrode 124, the first n-type electrode 125 and the first encapsulation layer 126, redundant descriptions thereof will be omitted.

The second planarization layer 116 is disposed on the plurality of light emitting elements LED. The second planarization layer 116 planarizes the upper portion of the substrate 110 on which the light emitting element LED is disposed, and can fix the light emitting element LED onto the substrate 110 together with the bonding layer 150.

Referring to FIG. 3, the common electrode CE is disposed on the plurality of light emitting elements LED. The common electrode CE is in a connected state, and can apply a voltage to the plurality of light emitting elements LED. Accordingly, the common electrode CE can be connected to the light emitting element disposed in the defective sub-pixel and the repair light emitting element LED_R and apply a voltage to the repair light emitting element LED_R. Specifically, the common electrode CE can be connected to the first light emitting element LED1 and the repair light emitting element LED_R and apply a voltage.

The common electrode CE can be formed of indium tin oxide (ITO), indium zinc oxide (IZO), indium tin zinc oxide (ITZO), zinc oxide (ZnO), and tin oxide (TO)-based transparent conductive oxides in order to transmit light emitted from the first light emitting layer 122 and the fourth light emitting layer 132, but the present disclosure is not limited thereto.

The common electrode CE is connected to the intermediate line 170 through a contact hole formed in the second planarization layer 116, and the intermediate line 170 can be connected to the low potential power supply line VSSL through a contact hole formed in the first planarization layer 115 and receive a common voltage. In addition, the common electrode CE can transmit the common voltage to the plurality of light emitting elements LED.

A bank 119 is disposed on the common electrode CE and the second planarization layer 116. The bank 119 is an insulating layer for distinguishing the plurality of sub-pixels SP adjacent from each other. The bank 119 can be disposed on the plurality of sub-pixels SP and can open upper surfaces of the plurality of light emitting elements LED.

The bank 119 can be formed of an organic insulating material including a black material, but is not limited thereto. As the bank 119 includes the black material, the bank 119 can prevent reflection of external light due to components disposed below the bank 119.

The third planarization layer 117 can be disposed on the bank 119 and the common electrode CE. The third planarization layer 117 can be a transparent insulating layer. The third planarization layer 117 can be formed of an organic material, for example, a single layer or multiple layers of polyimide or photo acryl, but is not limited thereto.

The third planarization layer 117 can fill an open area of the bank 119 and can planarize an upper portion of the display device 100.

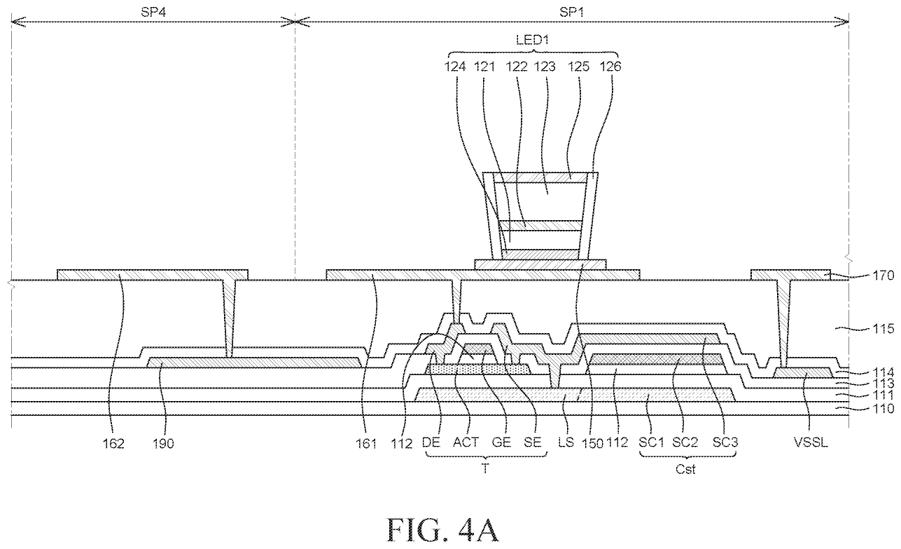

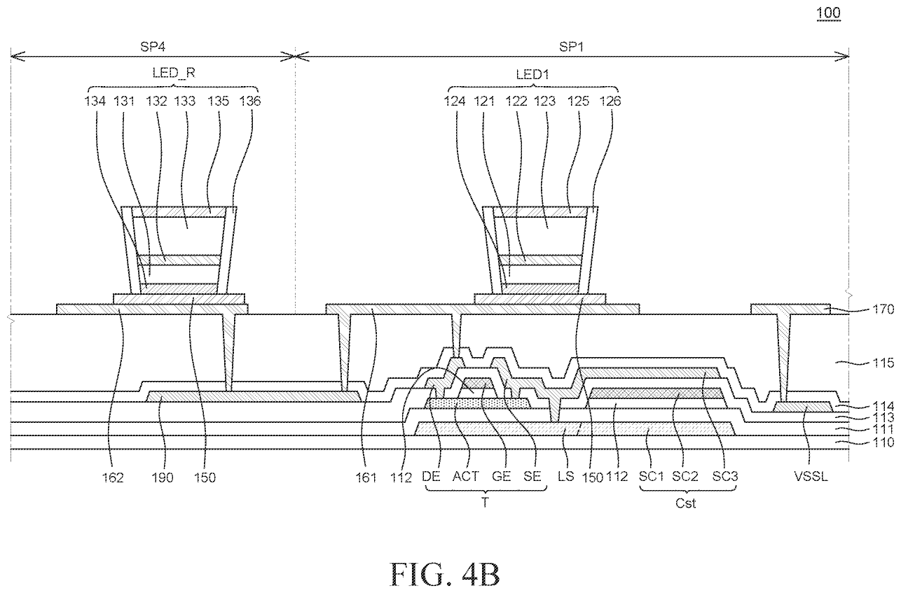

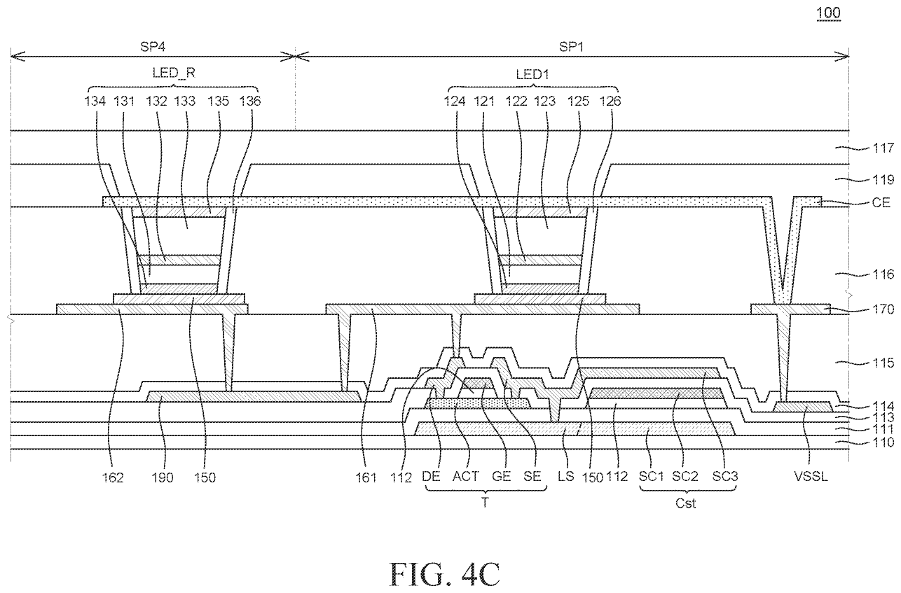

Hereinafter, a method of manufacturing the display device 100 according to an exemplary embodiment of the present disclosure will be described in detail with reference to FIGS. 4A to 4C.

FIGS. 4A to 4C are cross-sectional views for explaining a process of manufacturing the display device according to an exemplary embodiment of the present disclosure.

Referring to FIG. 4A, the plurality of light emitting elements LED can be transferred onto the substrate 110 on which the plurality of first reflective layers 161, the second reflective layer 162, the intermediate line 170, the plurality of bonding layers 150, the transistors T, and the storage capacitor Cst are disposed. First, the plurality of light emitting elements LED can be disposed to overlap the first reflective layers 161 disposed in the first sub-pixel SP1, the second sub-pixel SP2, and the third sub-pixel SP3 among the plurality of sub-pixels SP.

After the plurality of light emitting elements LED are transferred onto the substrate in the first sub-pixel SP1, the second sub-pixel SP2, and the third sub-pixel SP3 in a state illustrated in FIG. 4A, a turning-on inspection is performed. For example, it is possible to determine or detect whether the plurality of light emitting elements LED are normal (non-defective) or not (defective) by a non-contact electric field method. When a defective sub-pixel that does not emit light normally is detected among the plurality of sub-pixels SP, the repair light emitting element LED_R can be additionally transferred and provided.

Next, referring to FIG. 4B, the bonding layer 150 can be disposed in an area overlapping with the second reflective layer 162 in the fourth sub-pixel SP4, and the repair light emitting element LED_R can be disposed on the bonding layer 150. Accordingly, the repair light emitting element LED_R disposed on an upper portion of the bonding layer 150 and the second reflective layer 162 disposed on a lower portion of the bonding layer 150 can be electrically connected to each other. At this time, the repair light emitting element LED_R can be a light emitting element in the fourth sub-pixel SP4, that emits light of the same color as the first light emitting element LED1 which is a light emitting element disposed in a defective sub-pixel.

Next, a laser is irradiated onto the first reflective layer 161 disposed in the first sub-pixel SP1, which is detected to be the defective sub-pixel, so that the connection layer 190 and the first reflective layer 161 come into contact with each other. For example, a laser welding process can be performed to connect the first reflective layer 161 and the connection layer 190 in the area where the first reflective layer 161 and the connection layer 190 disposed in the first sub-pixel SP1 overlap each other. Accordingly, the connection layer 190 can be electrically connected to the first reflective layer 161, and the repair light emitting element LED_R can be electrically connected to the transistor T disposed in the first sub-pixel SP1 through the second reflective layer 162, the connection layer 190, and the first reflective layer 161. Accordingly, the transistor T disposed in the first sub-pixel SP1 can drive the repair light emitting element LED_R.

Referring to FIG. 4C, the second planarization layer 116 is formed on an entire surface of the plurality of light emitting elements LED. In this case, a contact hole for connecting the common electrode CE and the intermediate line 170 can be disposed in the second planarization layer 116.

Next, the common electrode CE and the bank 119 are disposed on the second planarization layer 116 and the plurality of light emitting elements LED. The common electrode CE can be disposed to extend between the plurality of light emitting elements LED in the plurality of sub-pixels SP and can be connected to the low potential power supply line VSSL through the intermediate line 170.

The bank 119 is disposed on the common electrode CE and the second planarization layer 116. The bank 119 can open the upper surfaces of the plurality of light emitting elements LED including the repair light emitting element LED_R.

Thereafter, the third planarization layer 117 can be disposed on the bank 119 and the common electrode CE.

In general, a defective sub-pixel that does not emit light normally or properly can occur in a plurality of sub-pixels disposed on a substrate. Accordingly, in order to repair the defective sub-pixel or otherwise compensate for the defective sub-pixel, a plurality of light emitting elements emitting light of the same color were placed in each of the plurality of sub-pixels. For example, when a plurality of sub-pixels were configured with a red sub-pixel, a green sub-pixel, and a blue sub-pixel, two red light emitting elements, two green light emitting elements, and two blue light emitting elements were disposed in the red sub-pixel, the green sub-pixel, and the blue sub-pixel, respectively. Accordingly, when a defective sub-pixel occurs, a repair light emitting element that emits light of the same color as the defective light emitting element is driven in place of the defective light emitting element in the defective sub-pixel. Meanwhile, when repair light emitting elements are disposed to correspond to the respective sub-pixels, a separate area can be needed to secure an arrangement space for the repair light emitting element. Therefore, as a distance between the light emitting elements that normally (properly) emit light increases, there can occur some difficulties or challenges in implementing a high-resolution display device.

Accordingly, in the display device 100 according to an exemplary embodiment of the present disclosure, an integrated repair area is disposed on the substrate 110. For example, when the display device 100 is configured with a red sub-pixel, a green sub-pixel, and a blue sub-pixel, the plurality of sub-pixels SP include the first sub-pixel SP1 which is a red sub-pixel, the second sub-pixel SP2 which is a green sub-pixel, the third sub-pixel SP3 which is a blue sub-pixel, and the fourth sub-pixel SP4 which is an area for repair. Accordingly, after first transferring the light emitting elements LED to the first sub-pixel SP1, the second sub-pixel SP2, and the third sub-pixel SP3, a turning-on inspection is performed. In a case where a defective sub-pixel which does not emit light normally is detected, the repair light emitting element LED_R can be selectively disposed in the fourth sub-pixel SP4. Thereafter, the repair light emitting element LED_R disposed in the fourth sub-pixel SP4 and the transistor T disposed in the defective sub-pixel can be electrically connected to drive the repair light emitting element LED_R disposed in fourth sub-pixel SP4 instead of the defective sub-pixel. Therefore, in the display device 100 according to an exemplary embodiment of the present disclosure, an arrangement space of the repair light emitting element LED_R can be reduced to accumulate the plurality of light emitting elements LED within a limited space, and a high-resolution display device with high PPI (pixel per inch) can be implemented.

In addition, in the display device 100 according to an exemplary embodiment of the present disclosure, the plurality of first reflective layers 161 and the second reflective layer 162 can reflect light emitted from the plurality of light emitting elements LED, upwardly of the plurality of light emitting elements LED, and can be used to repair defective sub-pixels. For example, when the first sub-pixel SP1 is defective, the first light emitting element LED1 and the first reflective layer 161 that is connected to the first light emitting element LED1 are connected to the repair light emitting element LED_R through the connection layer 190, so that the first sub-pixel SP1 can be repaired. Accordingly, in the display device 100 according to an exemplary embodiment of the present disclosure, repair of the plurality of sub-pixels SP can be performed by using the plurality of first reflective layers 161 and the second reflective layer 162 without arranging a separate repair line.

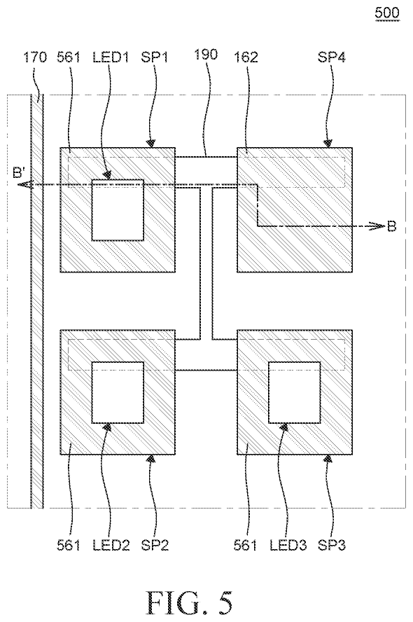

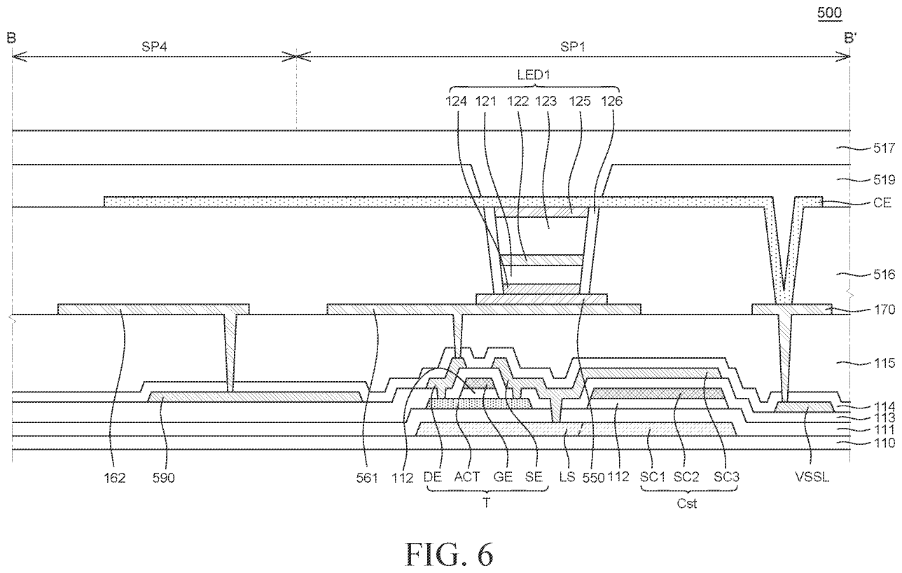

FIG. 5 is an enlarged plan view of a display device according to another exemplary embodiment of the present disclosure. FIG. 6 is a cross-sectional view taken along line B-B′ of FIG. 5.

Since other configurations of a display device 500 in FIGS. 5 and 6 are identical or substantially identical to those of the display device 100 of FIGS. 1 to 4, only except for differences in a plurality of sub-pixels SP, a plurality of first reflective layers 561, bonding layers 550, a second planarization layer 516, a third planarization layer 517, a connection layer 590, a bank 519, a common electrode CE, and a plurality of light emitting elements LED, redundant descriptions thereof will be omitted or may be briefly provided.

Referring to FIGS. 5 and 6, the plurality of sub-pixels SP are disposed in the display device 500. The plurality of sub-pixels SP can include a first sub-pixel SP1, a second sub-pixel SP2, a third sub-pixel SP3, and a fourth sub-pixel SP4.

Among the plurality of sub-pixels SP, the first sub-pixel SP1, the second sub-pixel SP2, and the third sub-pixel SP3 can be configured to emit light of different colors. Meanwhile, the fourth sub-pixel SP4 can be a non-emission sub-pixel. For example, the fourth sub-pixel SP4 can be a sub-pixel in which the light emitting element LED is not disposed so that light is not emitted.

Referring to FIG. 6, the connection layer 590 can be disposed on the interlayer insulating layer 113.

The connection layer 590 can be electrically connected to the second reflective layer 162. Meanwhile, the connection layer 590 can be insulated from the plurality of first reflective layers 561.

Referring to FIG. 6, the first passivation layer 114 and the first planarization layer 115 can be disposed on the connection layer 590, and the plurality of first reflective layers 561 and second reflective layer 162 can be disposed on the first planarization layer 115.

The plurality of first reflective layers 561 can be disposed between the plurality of light emitting elements LED and the plurality of transistors T in the first sub-pixel SP1, the second sub-pixel SP2, and the third sub-pixel SP3 and electrically connected to the plurality of transistors T.

Meanwhile, the plurality of first reflective layers 561 can be insulated from the connection layer 590 disposed below. Accordingly, the connection layer 590 and the second reflective layer 162 can be insulated from the plurality of transistors T and can be in an electrically floating state.

A plurality of bonding layers 550 are disposed on the plurality of first reflective layer 561. The plurality of bonding layers 550 can be disposed only in the first sub-pixel SP1, the second sub-pixel SP2, and the third sub-pixel SP3 among the plurality of sub-pixels SP.

The plurality of bonding layers 550 can electrically connect the plurality of light emitting elements LED disposed in the first sub-pixel SP1, the second sub-pixel SP2, and the third sub-pixel SP3, respectively. Accordingly, the plurality of transistors T and the plurality of light emitting elements LED can be electrically connected through the plurality of bonding layers 550, respectively.

The plurality of light emitting elements LED are disposed on the plurality of bonding layers 550. The plurality of light emitting elements LED can be disposed only in the first sub-pixel SP1, the second sub-pixel SP2, and the third sub-pixel SP3 among the plurality of sub-pixels SP. For example, a first light emitting element LED1, a second light emitting element LED2, and a third light emitting element LED3 can be disposed in the first sub-pixel SP1, the second sub-pixel SP2, and the third sub-pixel SP3, respectively.

The first light emitting element LED1, the second light emitting element LED2, and the third light emitting element LED3 can be disposed in areas overlapping with the plurality of bonding layer 550 in the first sub-pixel SP1, the second sub-pixel SP2, and the third sub-pixel SP3.

The second planarization layer 516 is disposed on the plurality of light emitting elements LED. The second planarization layer 516 planarizes the upper portion of the substrate 110 on which the light emitting element LED is disposed. The second planarization layer 516 can fix the light emitting element LED onto the substrate 110 together with the bonding layer 550. Accordingly, the second planarization layer 516 can be disposed in areas other than areas where the first light emitting element LED1, the second light emitting element LED, and the third light emitting element LED3 are disposed in the first sub-pixel SP1, the second sub-pixel SP2, and the third sub-pixel SP3. On the other hand, the second planarization layer 516 can be disposed in an area overlapping with an entire area of the fourth sub-pixel SP4.

The common electrode CE is disposed on the plurality of light emitting elements LED. A common voltage can be applied to the plurality of light emitting elements LED from the common electrode CE in the first sub-pixel SP1, the second sub-pixel SP2, and the third sub-pixel SP3. Meanwhile, in FIG. 6, the common electrode CE is illustrated as being disposed on the fourth sub-pixel SP4, but the common electrode CE is not limited thereto and can be dispose only on the first sub-pixel SP1, the second sub-pixel P2, and the third sub-pixel SP3.

The bank 519 is disposed on the common electrode CE and the second planarization layer 516. The bank 519 is disposed on the plurality of sub-pixels SP, and an area of the bank 519 overlapping with the plurality of light emitting elements LED can be open. In this case, the bank 519 can cover an entirety of the fourth sub-pixel SP4, which is a sub-pixel in which the light emitting element LED is not disposed. Accordingly, the bank 519 can prevent reflection of external light due to a metal such as the second reflective layer 162 disposed in the fourth sub-pixel SP4.

The third planarization layer 517 can be disposed on the bank 519 and the common electrode CE. The third planarization layer 517 fills the open area of the bank 519 and can planarize an upper portion of the display device 500.

In the display device 500 according to another exemplary embodiment of the present disclosure, an integrated repair area is disposed on the substrate 110. Accordingly, after first transferring the light emitting elements LED onto the first sub-pixel SP1, second sub-pixel SP2, and third sub-pixel SP3, a turning-on inspection is performed to determine whether the light emitting element LED is normal or not (e.g., defective or nor). Accordingly, when a defective sub-pixel is not detected in the plurality of sub-pixels SP, separate repair may not be performed. For example, when all of the plurality of light emitting elements LED disposed in the display device 500 are determined to be normal (e.g., non-defective), only the fourth sub-pixel SP4, which is an area for disposition of the repair light emitting element, among the plurality of sub-pixels SP can be a non-emission area. Accordingly, in the display device 500 according to another exemplary embodiment of the present disclosure, compared to a case where a plurality of light emitting elements emitting light of the same color are disposed in each of a plurality of sub-pixels to repair a defective sub-pixel, an arrangement space of the repair light emitting element LED_R can be reduced, and a plurality of light emitting elements LED can be accumulated in a limited area, so that it is possible to implement a high-resolution display device 500 with high pixel per inch (PPI).

The exemplary embodiments of the present disclosure can also be described as follows:

According to an aspect of the present disclosure, there is provided a display device. The display device comprises a plurality of sub-pixels including an emission sub-pixel and a repair sub-pixel. The display device comprises a light emitting element disposed in the emission sub-pixel. The display device comprises a transistor disposed in the emission sub-pixel. The display device comprises a first reflective layer disposed between the light emitting element and the transistor in the emission sub-pixel, and electrically connected to the transistor. The display device comprises a second reflective layer disposed in the repair sub-pixel. The display device comprises a connection layer disposed below the first reflective layer and the second reflective layer to overlap the first reflective layer and the second reflective layer.

The light emitting element can be electrically connected to the transistor through the first reflective layer.

The emission sub-pixel can include a first sub-pixel, a second sub-pixel, and a third sub-pixel configured to emit light of different colors.

The repair sub-pixel can include a fourth sub-pixel configured as a non-emission sub-pixel.

The connection layer can extend between the first to fourth sub-pixels and overlap the first reflective layer disposed in each of the first to third sub-pixels and the second reflective layer disposed in the fourth sub-pixel.

The transistor is not disposed in the repair sub-pixel. The connection layer can be electrically connected to the second reflective layer. The emission sub-pixel can be detected to emit light normally, and the connection layer can be insulated from the first reflective layer.

The display device can further comprise a bank disposed on the plurality of sub-pixels, and having an open area overlapping with the light emitting element. The bank can cover an entirety of the repair sub-pixel.

The connection layer and the second reflective layer can be electrically floating. The emission sub-pixel can be detected as a defective sub-pixel that does not emit light normally. A repair light emitting element, that emits light of the same color as the light emitting element disposed in the defective sub-pixel, can be disposed in the repair sub-pixel.

The connection layer can be electrically connected to the first reflective layer disposed in the defective sub-pixel.

The repair light emitting element can be electrically connected to the transistor disposed in the defective sub-pixel through the second reflective layer, the connection layer and the first reflective layer.

The display device can further comprise a common electrode connected to the light emitting element disposed in the defective sub-pixel and the repair light emitting element disposed in the repair sub-pixel.

The display device can further comprise an intermediate line disposed below the common electrode and connected to the common electrode. The display device can further comprise a low potential power supply line disposed below the intermediate line and connected to the intermediate line.

The display device can further comprise a bank disposed on the plurality of sub-pixels and having open areas overlapping the light emitting element and the repair light emitting element.

The connection layer can be disposed on a same layer as an electrode included in the transistor.

The display device can further comprise a bonding layer disposed between the first reflective layer and the light emitting element. The bonding layer can comprise a eutectic metal.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application, which examples are to be construed as non-exclusive. It is intended, therefore, that the specification and examples be considered as example only, with a true scope and spirit being indicated by the following claims and their full scope of equivalents.

What is claimed is:

1. A display device, comprising:
a plurality of sub-pixels including at least one emission sub-pixel and a repair sub-pixel disposed on a substrate;
a light emitting element disposed in the at least one emission sub-pixel;
a transistor disposed in the emission sub-pixel;
a first reflective layer disposed between the light emitting element and the transistor in the at least one emission sub-pixel, and electrically connected to the transistor;
a second reflective layer disposed in the repair sub-pixel; and
a connection layer disposed below the first reflective layer and the second reflective layer to overlap the first reflective layer and the second reflective layer.

2. The display device of claim 1, wherein the light emitting element is electrically connected to the transistor through the first reflective layer.

3. The display device of claim 1, wherein the at least one emission sub-pixel includes a first sub-pixel, a second sub-pixel, and a third sub-pixel configured to emit light of different colors.

4. The display device of claim 3, wherein the repair sub-pixel includes a fourth sub-pixel configured as a non-emission sub-pixel.

5. The display device of claim 4, wherein the connection layer extends between the first to fourth sub-pixels, and overlaps the first reflective layer disposed in each of the first to third sub-pixels and overlaps the second reflective layer disposed in the fourth sub-pixel.

6. The display device of claim 1, wherein the transistor is not disposed in the repair sub-pixel.

7. The display device of claim 1, wherein the connection layer is electrically connected to the second reflective layer.

8. The display device of claim 1, wherein the at least one emission sub-pixel is detected to emit light properly, and the connection layer is insulated from the first reflective layer.

9. The display device of claim 8, further comprising:
a bank disposed on the plurality of sub-pixels, and having an open area overlapping with the light emitting element,
wherein the bank covers an entirety of the repair sub-pixel.

10. The display device of claim 8, wherein the connection layer and the second reflective layer are electrically floating.

11. The display device of claim 1, wherein when one of the at least one emission sub-pixel is detected as a defective sub-pixel that does not emit light properly, a repair light emitting element, that emits light of a same color as the light emitting element disposed in the defective sub-pixel, is disposed in the repair sub-pixel.

12. The display device of claim 11, wherein the connection layer is electrically connected to the first reflective layer disposed in the defective sub-pixel.

13. The display device of claim 12, wherein the repair light emitting element is electrically connected to the transistor disposed in the defective sub-pixel through the second reflective layer, the connection layer and the first reflective layer.

14. The display device of claim 11, further comprising:
a common electrode connected to the light emitting element disposed in the defective sub-pixel and the repair light emitting element disposed in the repair sub-pixel.

15. The display device of claim 14, further comprising:
an intermediate line disposed below the common electrode and connected to the common electrode; and
a low potential power supply line disposed below the intermediate line and connected to the intermediate line.

16. The display device of claim 11, further comprising:
a bank disposed on the plurality of sub-pixels and having open areas overlapping with the light emitting element and the repair light emitting element.

17. The display device of claim 1, wherein the connection layer is disposed on a same layer as an electrode included in the transistor.

18. The display device of claim 1, further comprising:
a bonding layer disposed between the first reflective layer and the light emitting element.

19. The display device of claim 18, wherein the bonding layer comprises a eutectic metal.
